(19) United States
(12) Patent Application Publication
(10) Pub. No.: US 2002/0135026 A1
(43) Pub. Date: Sep. 26, 2002

(54) Semiconductor device, memory system and electronic apparatus

(76) Inventors: Junichi Karasawa, Nagano-ken (JP); Kunio Watanabe, Sakata-shi (JP)

Correspondence Address: HOGAN & HARTSON L.L.P., 500 S. GRAND AVENUE, SUITE 1900, LOS ANGELES, CA, 90071-2611, US

(21) Appl. No.: 10/072,618

(22) Filed: Feb. 7, 2002

(30) Foreign Application Priority Data
Mar. 26, 2001 (JP) 2001-088309(P)
Oct. 31, 2001 (JP) 2001-334689(P)

(51) Int. Cl. H01L 29/76

(52) U.S. Cl. 257/377

(57) ABSTRACT

A semiconductor device is provided with an SRAM memory cell. The semiconductor device includes a first gate-gate electrode layer, a second gate-gate electrode layer, a first drain-drain wiring layer, a second drain-drain wiring layer, a first drain-gate wiring layer and a second drain-gate wiring layer. The first drain-gate wiring layer and an upper layer and a lower layer of the second drain-gate wiring layer are located in different layers, respectively. The diameter of a through hole in the first interlayer dielectric layer is equal to or less than the diameter of through holes in the second and third interlayer dielectric layers.

Japanese Patent Application No. 2001-88309, filed on Mar. 26, 2001 and Japanese Paten Application No. 2001-334689, field on Oct. 31, 2001, are hereby incorporated by reference in its entirety.

### BACKGROUND OF THE INVENTION

The present invention relates to semiconductor devices, such as, for example, static random access memories (SRAMs), and memory systems and electronic apparatuses provided with the same.

SRAMs, one type of semiconductor memory devices, do not require a refreshing operation and therefore have a property that can simplify the system and lower power consumption. For this reason, the SRAMs are prevailingly used as memories for electronic equipment, such as, for example, mobile phones.

### BRIEF SUMMARY OF THE INVENTION

The present invention may provide a semiconductor device that can reduce its cell area.

The present invention may further provide a memory system and an electronic apparatus that includes a semiconductor device in accordance with the present invention.

1. Semiconductor Device

A semiconductor device in accordance with a first aspect of the present invention is provided with a memory cell including a first driver transistor, a second driver transistor, a first transfer transistor, and a second transfer transistor, a first load transistor, and a second load transistor, and the semiconductor device comprises:

a field in which a source region and a drain region of each of the first and the second driver transistors, the first and the second transfer transistors and the first and the second load transistors;

a first conductive layer formed on the field;

a second conductive layer located in a layer over the first conductive layer; and

a first interlayer dielectric layer formed between the first conductive layer and the second conductive layer; and

a second interlayer dielectric layer located in a layer over the first interlayer dielectric layer,

wherein a first through hole is formed in the first interlayer dielectric layer, and a second through hole is formed in the second interlayer dielectric layer, and

wherein a diameter of the first through hole is equal to or less than a diameter of the second through hole.

Here, the “first through hole” includes a through hole for a contact section that electrically connects the first conductive layer and the second conductive layer and a through hole for a contact section that electrically connects an impurity layer that is a component of the transistor and the second conductive layer.

In accordance with this aspect, short-circuit between the contact section provided in the first through hole and a given conductive section may be decreased for the reasons described below.

The semiconductor device in accordance with this aspect may take any one of the following features.

(a) The memory cell may comprise:

a first gate-gate electrode layer including a gate electrode of the first load transistor and a gate electrode of the first driver transistor;

a second gate-gate electrode layer including a gate electrode of the second load transistor and a gate electrode of the second driver transistor;

a first drain-drain wiring layer which forms a part of an electrical connection between a drain region of the first load transistor and a drain region of the first driver transistor;

a second drain-drain wiring layer which forms a part of an electrical connection between a drain region of the second load transistor and a drain region of the second driver transistor;

a first drain-gate wiring layer which forms a part of an electrical connection between the first gate-gate electrode layer and the second drain-drain wiring layer; and

a second drain-gate wiring layer which forms a part of an electrical connection between the second gate-gate electrode layer and the first drain-drain wiring layer, and

wherein the first drain-gate wiring layer and the second drain-gate wiring layer are located in different conductive layers, respectively.

Here, the “wiring layer” means a conductive layer disposed over a field or an interlayer dielectric layer.

In accordance with this aspect, the first drain-gate wiring layer and the second drain-gate wiring layer are located in different layers, respectively. As a result, the pattern density of a wiring layer in each of the layers where the first drain-gate wiring layer and the second drain-gate wiring layer are formed, respectively, may be reduced and the cell area may be made smaller, compared to the case where the first drain-gate wiring layer and the second drain-gate wiring layer are formed in the same layer.

(b) A diameter of the first through hole may be smaller than a diameter of the second through hole. As a result, short-circuit between the contact section provided in the first through hole and a given conductive section may be reduced.

(c) The first through hole may have a minimum size that is achieved by a manufacturing process technology applied to manufacturing the semiconductor device.

(d) The first through hole may be formed by using a first mask layer and a second mask layer which is provided on a sidewall of an opening of the first mask layer. More specifically, the first through hole may be formed by a process including a step of forming the first mask layer, and a step of forming the second mask layer on a sidewall of the opening of the first mask layer. As a result, the first through hole having a small diameter may be readily formed.

The first mask layer may be a resist layer, and the second mask layer may adjust a width of the opening of the mask layer.

(e) The first drain-gate wiring layer may be electrically connected to the second drain-drain wiring layer through a contact section, and

the second drain-gate wiring layer may be electrically connected to the second gate-gate electrode layer through a contact section, and electrically connected to the first drain-drain wiring layer through a contact section.

(f) The first drain-gate wiring layer may be located in a layer below the second drain-gate wiring layer.

(g) The first drain-gate wiring layer may be located in a layer in which the first gate-gate electrode layer is provided.

(h) The second drain-gate wiring layer may be formed across a plurality of layers.

In the feature of (h), the second drain-gate wiring layer may include a lower layer of the second drain-gate wiring layer and an upper layer of the second drain-gate wiring layer, and

the upper layer may be located in a layer over the lower layer, and is electrically connected to the lower layer.

In this feature, the upper layer may be electrically connected to the lower layer through a contact section.

In this feature, the first gate-gate electrode layer, the second gate-gate electrode layer and the first drain-gate wiring layer may be located in a first conductive layer,

the first drain-drain wiring layer, the second drain-drain wiring layer and the lower layer may be located in a second conductive layer, and

the upper layer may be located in a third conductive layer.

(i) The second conductive layer may be a nitride layer of a refractory metal (for example, titanium nitride). As a result of the second conductive layer being a nitride layer of a refractory metal, the thickness of the second conductive layer may be reduced, and miniaturizing processing may be readily performed. Accordingly, the cell area may be reduced.

(j) The second conductive layer may have a thickness of 100 nm to 200 nm.

2. Memory System

A memory system in accordance with a second aspect of the present invention is provided with the semiconductor device of the first aspect.

3. Electronic Apparatus

An electronic apparatus in accordance with a third aspect of the present invention is provided with the semiconductor device of the first aspect.

### BRIEF DESCRIPTION OF THE SEVERAL VIEWS OF THE DRAWING

FIG. 1 shows a relationship between an equivalent circuit of an SRAM in accordance with the present embodiment and corresponding conductive layers;

FIG. 2 schematically shows a plan view of a field of the memory cell of the SRAM in accordance with the present embodiment;

FIG. 3 schematically shows a plan view of a first conductive layer of the memory cell of the SRAM in accordance with the present embodiment;

FIG. 4 schematically shows a plan view of a second conductive layer of the memory cell of the SRAM in accordance with the present embodiment;

FIG. 5 schematically shows a plan view of a third conductive layer of the memory cell of the SRAM in accordance with the present embodiment;

FIG. 6 schematically shows a plan view of a fourth conductive layer of the memory cell of the SRAM in accordance with the present embodiment;

FIG. 7 schematically shows a plan view of the field and the first conductive layer of the memory cell of the SRAM in accordance with the present embodiment;

FIG. 8 schematically shows a plan view of the field and the second conductive layer of the memory cell of the SRAM in accordance with the present embodiment;

FIG. 9 schematically shows a plan view of the first conductive layer and the second conductive layer of the memory cell of the SRAM in accordance with the present embodiment;

FIG. 10 schematically shows a plan view of the second conductive layer and the third conductive layer of the memory cell of the SRAM in accordance with the present embodiment;

FIG. 11 schematically shows a plan view of the third conductive layer and the fourth conductive layer of the memory cell of the SRAM in accordance with the present embodiment;

FIG. 12 schematically shows a cross-sectional view taken along a line A-A shown in FIG. 2 to FIG. 11;

FIG. 13 schematically shows a cross-sectional view taken along a line B-B shown in FIG. 2 to FIG. 11;

5 FIG. 14 shows a block diagram of a part of a mobile telephone system provided with the SRAM in accordance with the present embodiment;

FIG. 15 shows a perspective view of a mobile telephone that is provided with the mobile telephone system shown in FIG. 14;

FIG. 16 shows an illustration to describe effects;

FIGS. 17A and 17B schematically show in cross sections the steps of forming a contact section; and

FIGS. 18A and 18B schematically show in cross sections the steps of forming the contact section.

### DETAILED DESCRIPTION OF THE EMBODIMENT

An embodiment of the present invention is described. The present embodiment is the one in which a semiconductor device in accordance with the present invention is applied to in an SRAM.

1. Equivalent Circuit of SRAM

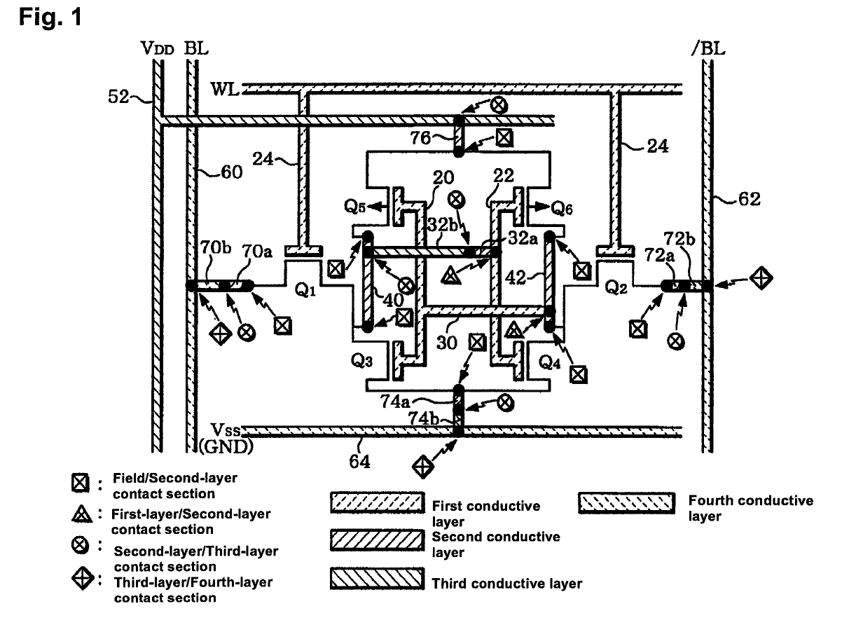

FIG. 1 shows a relationship between an equivalent circuit of an SRAM in accordance with the present embodiment and corresponding conductive layers. The SRAM of the present embodiment is a type in which one memory cell is formed with six MOS field effect transistors. In other words, one CMOS inverter is formed with an n-channel type driver transistor Q3 and a p-channel type load transistor Q5. Also, one CMOS inverter is formed with an n-channel type driver transistor Q4 and a p-channel type load transistor Q6. These two CMOS inverters are cross-coupled to form a flip-flop. Further, one memory cell is formed from this flip-flop and n-channel type transfer transistors Ql and Q2.

2. Structure of SRAM

A structure of the SRAM is described below. First, each figure is briefly described.

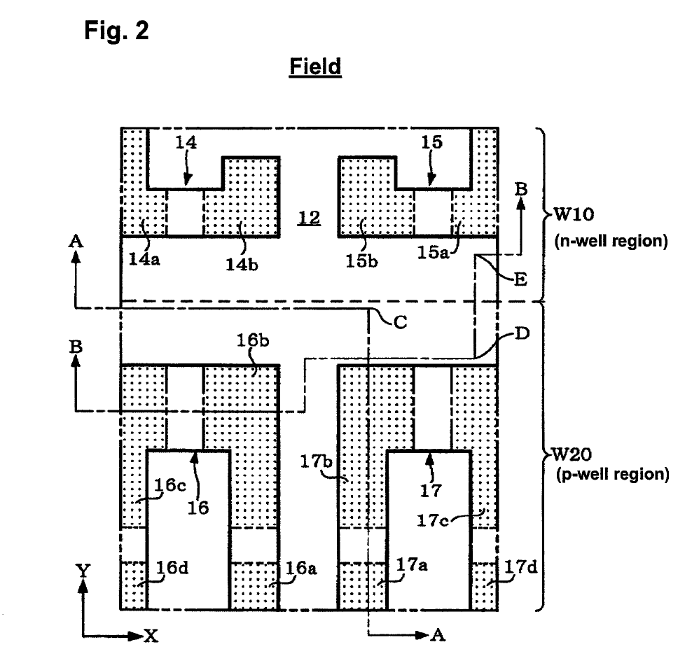

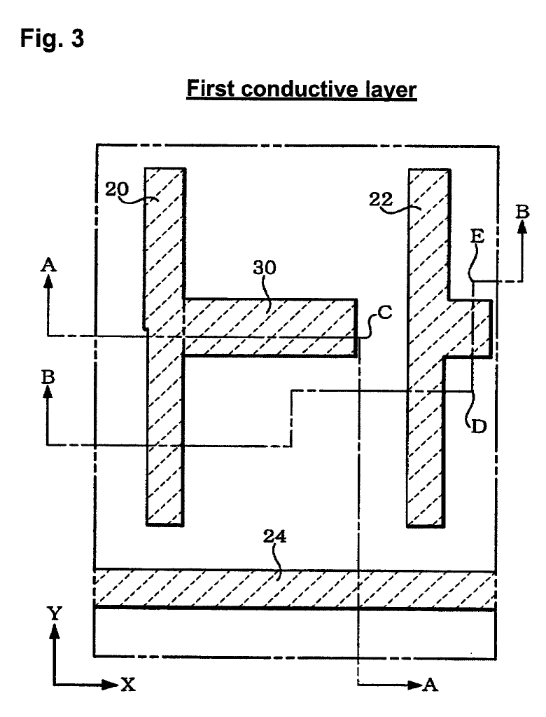

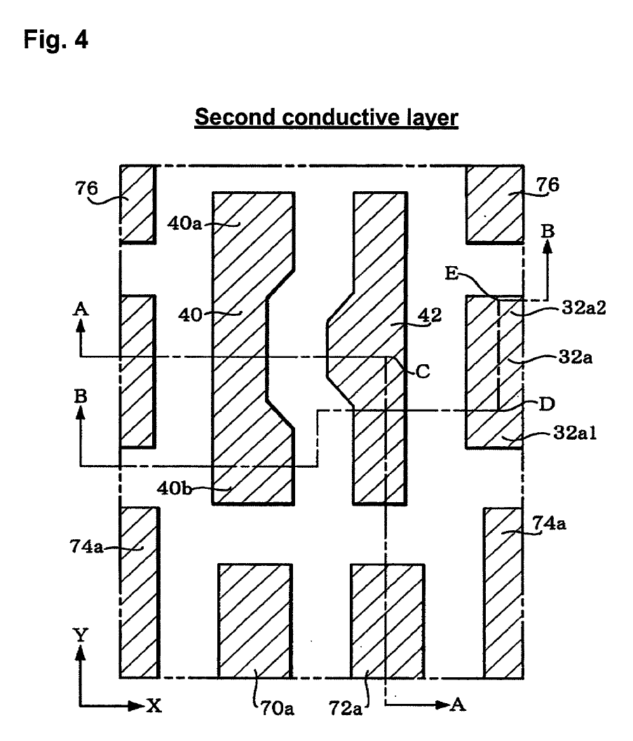

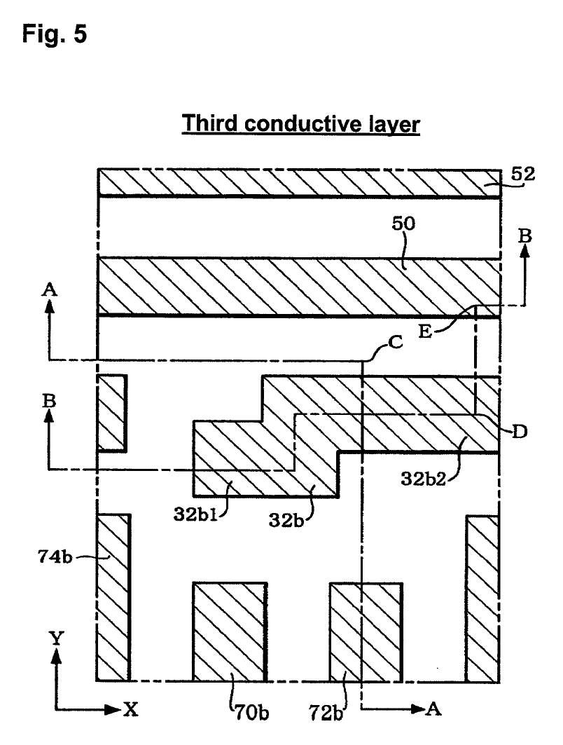

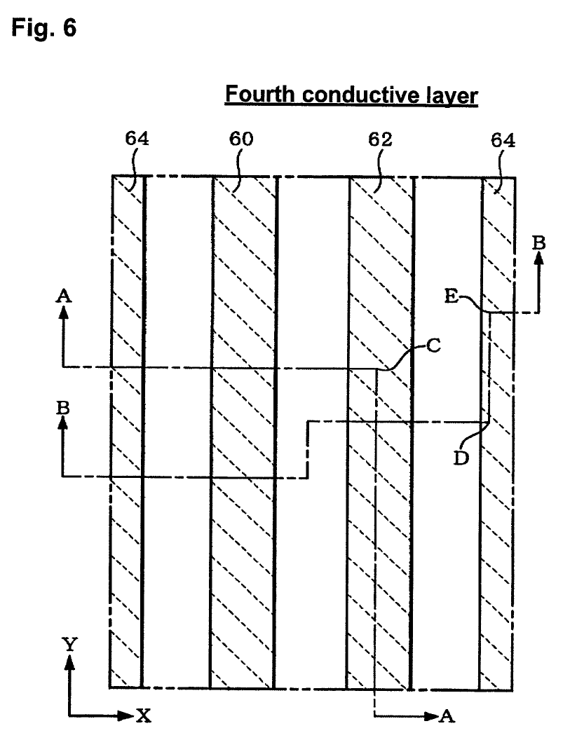

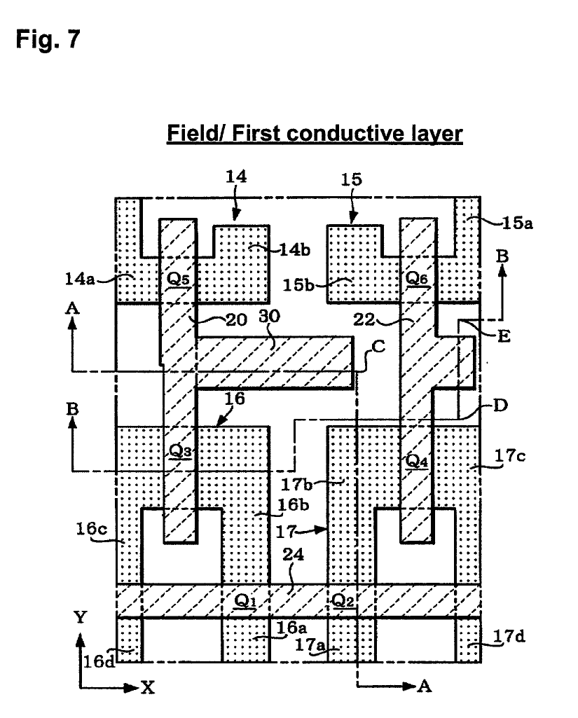

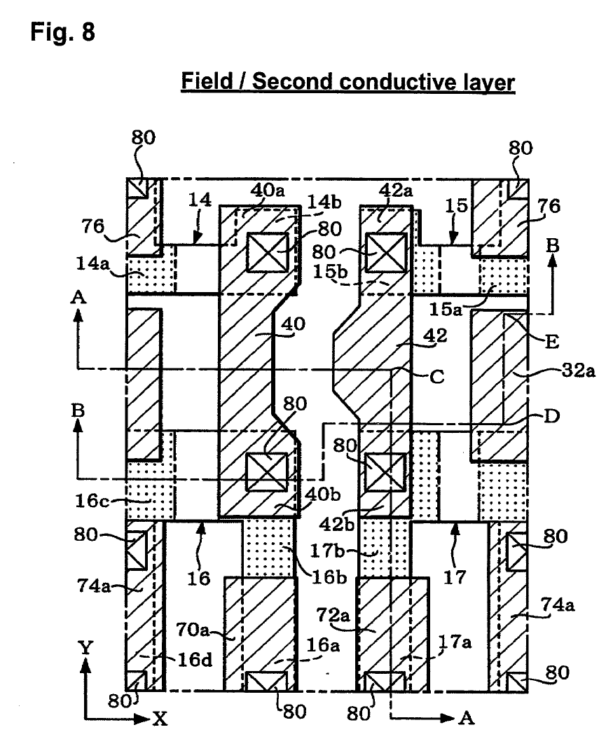

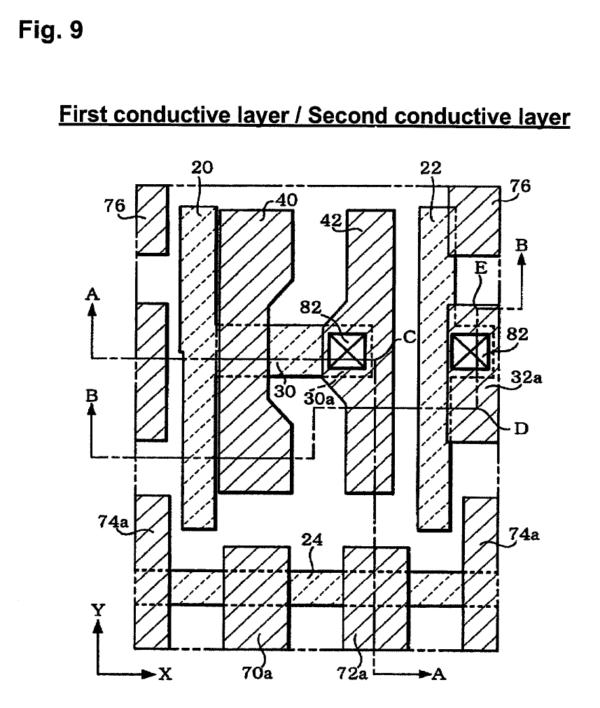

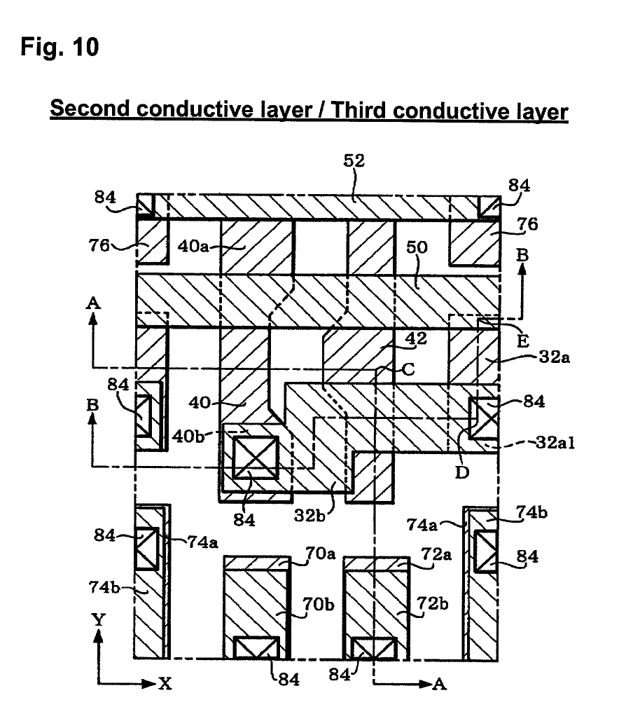

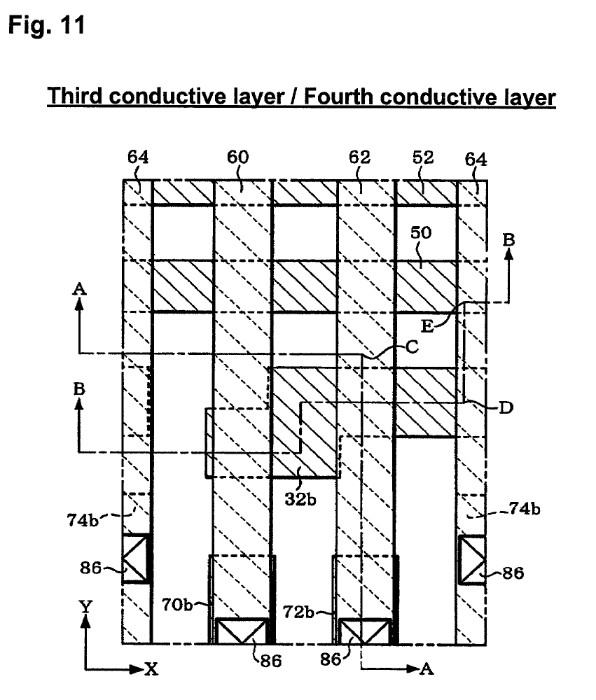

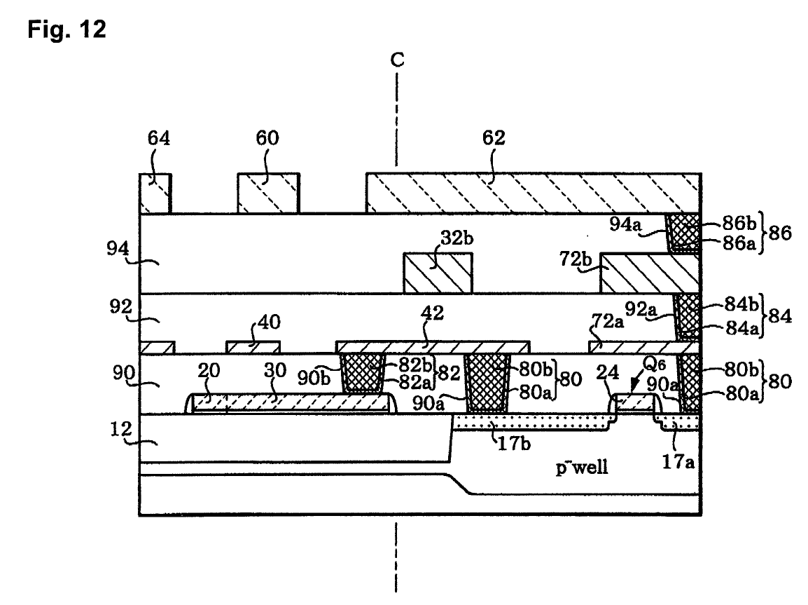

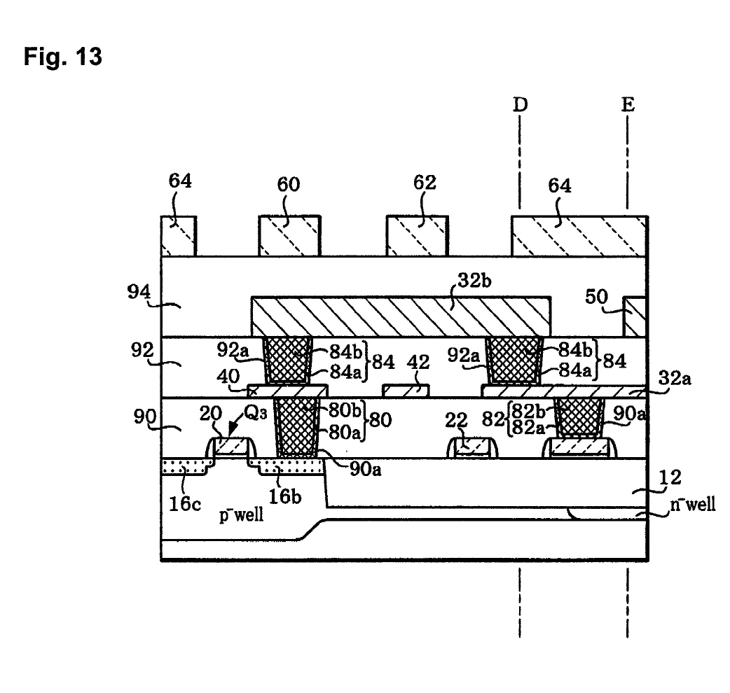

FIG. 1 shows a relationship between an equivalent circuit of an SRAM in accordance with the present embodiment and corresponding conductive layers. FIG. 2 schematically shows a plan view of a field of the memory cell of the SRAM in accordance with the present embodiment. FIG. 3 schematically shows a plan view of a first conductive layer of the memory cell of the SRAM in accordance with the present embodiment. FIG. 4 schematically shows a plan view of a second conductive layer of the memory cell of the SRAM in accordance with the present embodiment. FIG. 5 schematically shows a plan view of a third conductive layer of the memory cell of the SRAM in accordance with the present embodiment. FIG. 6 schematically shows a plan view of a fourth conductive layer of the memory cell of the SRAM in accordance with the present embodiment. FIG. 7 schematically shows a plan view of the field and the first conductive layer of the memory cell of the SRAM in accordance with the present embodiment. FIG. 8 schematically shows a plan view of the field and the second conductive layer of the memory cell of the SRAM in accordance with the present embodiment. FIG. 9 schematically shows a plan view of the first conductive layer and the second conductive layer of the memory cell of the SRAM in accordance with the present embodiment. FIG. 10 schematically shows a plan view of the second conductive layer and the third conductive layer of the memory cell of the SRAM in accordance with the present embodiment. FIG. 11 schematically shows a plan view of the third conductive layer and the fourth conductive layer of the memory cell of the SRAM in accordance with the present embodiment. FIG. 12 schematically shows a cross-sectional view taken along a line A-A shown in FIG. 2 to FIG. 11. FIG. 13 schematically shows a cross-sectional view taken along a line B-B shown in FIG. 2 to FIG. 11.

The SRAM is formed including an element forming region formed in a field, a first conductive layer, a second conductive layer, a third conductive layer, and a fourth conductive layer. The structure of each of the field, and the first through fourth conductive layers is concretely described below.

2.1 Field

Referring to FIG. 2, the field is described. The field includes first through fourth active regions 14, 15, 16 and 17, and an element isolation region 12. The first through fourth active regions 14, 15, 16 and 17 are defined by the element isolation region 12. A region on the side where the first and second active regions 14 and 15 are formed is an n-type well region W10, and a region on the side where the third and fourth active regions 16 and 17 are formed is a p-type well region W20.

The first active region 14 and the second active region are disposed in a symmetrical relation in a plane configuration. Also, the third active region 16 and the fourth active region 17 are disposed in a symmetrical relation in a plane configuration.

The first load transistor Q5 is formed in the first active region 14. In the first active region 14, a first p⁺-type impurity layer 14a and a second p⁺-type impurity layer 14b are formed. The first p⁺-type impurity layer 14a functions as a source of the first load transistor Q5. The second p⁺-type impurity layer 14b functions as a drain of the first load transistor Q5.

The second load transistor Q6 is formed in the second active region 15. In the second active region 15, a third p⁺-type impurity layer 15a and a fourth p⁺-type impurity layer 15b are formed. The third p⁺-type impurity layer 15a functions as a source of the second load transistor Q6. The fourth p⁺-type impurity layer 15b functions as a drain of the second load transistor Q6.

In the third active region 16, the first driver transistor Q3 and the first transfer transistor Q1 are formed. In the third active region 16, first through third n⁺-type impurity layers 16a, 16b and 16c that are to become components of the transistors Q1 and Q3, and a fifth p⁺-type impurity layer 16d that composes a well contact region are formed. The first n⁺-type impurity layer 16a functions as a source or a drain of the first transfer transistor Q1. The second n⁺-type impurity layer 16b functions as a drain of the first driver transistor Q3, and a source or a drain of the first transfer transistor Q1. The third n⁺-type impurity layer 16c functions as a source of the first driver transistor Q3.

In the fourth active region 17, the second driver transistor Q4 and the second transfer transistor Q2 are formed. In the fourth active region 17, fourth through sixth n⁺-type impurity layers 17a, 17b and 17c that are to become components of the transistors Q2 and Q4, and a sixth p⁺-type impurity layer 17d that composes a well contact region are formed. The fourth n⁺-type impurity layer 17a functions as a source or a drain of the second transfer transistor Q2. The fifth n⁺-type impurity layer 17b functions as a drain of the second driver transistor Q4, and a source or a drain of the second transfer transistor Q2. The sixth n⁺-type impurity layer 17c functions as a source of the second driver transistor Q4.

2.2 First Conductive Layer

Next, referring to FIG. 3 and FIG. 7, the first conductive layer is described. It is noted that the first conductive layer means a conductive layer that is formed on the semiconductor layer 10.

The first conductive layer includes a first gate-gate electrode layer 20, a second gate-gate electrode layer 22, a first drain-gate wiring layer 30 and an auxiliary word line 24.

The first gate-gate electrode layer 20 and the second gate-gate electrode layer 22 are formed in a manner to extend along a Y direction. The first drain-gate wiring layer 30 and the auxiliary word line 24 are formed in a manner to extend along an X direction.

Components of the first conductive layer are described concretely below.

1) First Gate-Gate Electrode Layer

The first gate-gate electrode layer 20 is formed in a manner to traverse the first active region 14 and the third active region 16, as shown in FIG. 7. The first gate-gate electrode layer 20 functions as a gate electrode of the first load transistor Q5 and the first driver transistor Q3.

The first gate-gate electrode layer 20 is formed in a manner to pass between the first p⁺-type impurity layer 14a and the second p⁺-type impurity layer 14b, in the first active region 14. In other words, the first gate-gate electrode layer 20, the first p⁺-type impurity layer 14a and the second p⁺-type impurity layer 14b form the first load transistor Q5. Also, the first gate-gate electrode layer 20 is formed in a manner to pass between the second n⁺-type impurity layer 16a and the third n⁺-type impurity layer 16c, in the third active region 16. In other words, the first gate-gate electrode layer 20, the second n⁺-type impurity layer 16a and the third n⁺-type impurity layer 16c form the first driver transistor Q3.

2) First Drain-Gate Wiring Layer

The first drain-gate wiring layer 30 is formed in a manner to extend in the X direction from a side section of the first gate-gate electrode layer 20 toward the second gate-gate electrode layer 22. Also, as shown in FIG. 7, the first drain-gate wiring layer 30 is formed at least between the first active region 14 and the third active region 16.

3) Second Gate-Gate Electrode Layer

The second gate-gate electrode layer 22 is formed in a manner to traverse the second active region 15 and the fourth active region 17, as shown in FIG. 7. The second gate-gate electrode layer 22 functions as a gate electrode of the second load transistor Q6 and the second driver transistor Q4.

The second gate-gate electrode layer 22 is formed in a manner to pass between the third p⁺-type impurity layer 15a and the fourth p⁺-type impurity layer 15b, in the second active region 15. In other words, the second gate-gate electrode layer 22, the third p⁺-type impurity layer 15a and the fourth p⁺-type impurity layer 15b form the second load transistor Q6. Also, the second gate-gate electrode layer 22 is formed in a manner to pass between the fifth n⁺-type impurity layer 17b and the sixth n⁺-type impurity layer 17c, in the fourth active region 17. In other words, the second gate-gate electrode layer 22, the fifth n⁺-type impurity layer 17b and the sixth n⁺-type impurity layer 17c form the second driver transistor Q4.

4) Auxiliary Word Line

The auxiliary word line 24 is formed in a manner to traverse the third active region 16 and the fourth active region 17, as shown in FIG. 7. The auxiliary word line 24 functions as a gate electrode of the first and second transfer transistors Q1 and Q2.

The auxiliary word line 24 is formed in a manner to pass between the first n*-type impurity layer 16a and the second n⁺-type impurity layer 16b, in the third active region 16. In other words, the auxiliary word line 24, the first n⁺-type impurity layer 16a and the second n⁺-type impurity layer 16b form the first transfer transistor Q1. Also, the auxiliary word line 24 is formed in a manner to pass between the fourth n⁺-type impurity layer 17a and the fifth n⁺-type impurity layer 17b, in the fourth active region 17. In other words, the auxiliary word line 24, the fourth n⁺-type impurity layer 17a and the fifth n⁺-type impurity layer 17b form the second transfer transistor Q2.

5) Cross-sectional Structure of First Conductive Layer and others

The first conductive layer may be formed by successively depositing a polysilicon layer and a silicide layer in layers.

As shown in FIG. 12 and FIG. 13, a first interlayer dielectric layer 90 is formed on the field and the first conductive layer. The first interlayer dielectric layer 90 may be formed through a planarization process utilizing, for example, a chemical mechanical polishing method.

2.3 Second Conductive Layer

Referring to FIG. 4, FIG. 8 and FIG. 9, the second conductive layer is described below. It is noted that the second conductive layer means a conductive layer that is formed on the first interlayer dielectric layer 90.

The second conductive layer includes, as shown in FIG. 4, a first drain-drain wiring layer 40, a second drain-drain wiring layer 42, a lower layer 32a of the second drain-gate wiring layer, a first BL contact pad layer 70a, a first bar-BL contact pad layer 72a, a first Vss contact pad layer 74a and a Vdd contact pad layer 76.

The first drain-drain wiring layer 40, the second drain-drain wiring layer 42 and the lower layer 32a of the second drain-gate wiring layer are formed in a manner to extend along the Y direction. The first drain-drain wiring layer 40, the second drain-drain wiring layer 42 and the lower layer 32a of the second drain-gate wiring layer are successively disposed in the X direction.

Components of the second conductive layer are concretely described below.

1) First Drain-Drain Wiring Layer

The first drain-drain wiring layer 40 has portions that overlap the first active region 14 and the third active region 16 as viewed in a plan view (see FIG. 8). More concretely, one end portion 40a of the first drain-drain wiring layer 40 is located above the second p⁺-type impurity layer 14b. The one end portion 40a of the first drain-drain wiring layer 40 and the second p⁺-type impurity layer 14b are electrically connected to each other through a contact section between the field and the second conductive layer (herein blew referred to as a “field/second-layer contact section”) 80. The other end portion 40b of the first drain-drain wiring layer 40 is located above the second n⁺-type impurity layer 16b. The other end portion 40b of the first drain-drain wiring layer 40 and the second n⁺-type impurity layer 16b are electrically connected to each other through the field/second-layer contact section 80.

2) Second Drain-Drain Wiring Layer

The second drain-drain wiring layer 42 has portions that overlap the second active region 15 and the fourth active region 17 as viewed in a plan view (see FIG. 8). More concretely, one end portion 42a of the second drain-drain wiring layer 42 is located above the fourth p⁺-type impurity layer 15b. The one end portion 42a of the second drain-drain wiring layer 42 and the fourth p⁺-type impurity layer 15b are electrically connected to each other through the field/second-layer contact section 80. The other end portion 42b of the second drain-drain wiring layer 42 is located above the fifth n⁺-type impurity layer 17b. The other end portion 42b of the second drain-drain wiring layer 42 and the fifth n⁺-type impurity layer 17b are electrically connected A to each other through the field/second-layer contact section 80.

Further, the second drain-drain wiring layer 42 has a portion that overlaps an end portion 30a of the first drain-gate wiring layer 30 as viewed in a plan view (see FIG. 9). The second drain-drain wiring layer 42 and the end portion 30a of the first drain-gate wiring layer 30 are electrically connected to each other through a contact section between the first conductive layer and the second conductive layer (hereafter referred to as a “first-layer/second-layer contact section”) 82.

3) Lower Layer of Second Drain-Gate Wiring Layer

The lower layer 32a of the second drain-gate wiring layer is formed on the opposite side of the first drain-drain wiring layer 40 with respect to the second drain-drain wiring layer 42 as being a reference. The lower layer 32a of the second drain-gate wiring layer has a portion that overlaps the second gate-gate electrode layer 22 as viewed in a plan view (see FIG. 9). The lower layer 32a of the second drain-gate wiring layer, and the second gate-gate electrode layer 22 are electrically connected to each other through the first-layer/second-layer contact section 82.

4) First BL Contact Pad Layer

The first BL contact pad layer 70a is located above the first n⁺-type impurity layer 16a in the third active region 16 (see FIG. 8). The first BL contact pad layer 70a and the first n⁺-type impurity layer 16a are electrically connected to each other through the field/second-layer contact section 80.

5) First Bar-BL Contact Pad Layer The first bar-BL contact pad layer 72a is located above the fourth n⁺-type impurity layer 17a in the fourth active region 17 (see FIG. 8). The first bar-BL contact pad layer 72a and the fourth n⁺-type impurity layer 17a are electrically connected to each other through the field/second-layer contact section 80.

6) First Vss Contact Pad Layer

The first Vss contact pad layers 74a are located above the sources of the driver transistors Q3 and Q4 (for example, the third n⁺-type impurity layer 16c) and the well contact region (for example, the fifth p⁺-type impurity layer 16d) (see FIG. 8). Each of the first Vss contact pad layers 74a is electrically connected to the source of each of the driver transistors Q3 and Q4 (for example, the third n⁺-type impurity layer 16c) through the field/second-layer contact section 80. Also, the first Vss contact pad layer 74a is electrically connected to the well contact region (for example, the fourth p⁺-type impurity layer 16d) through the field/second-layer contact section 80.

7) Vdd Contact Pad Layer

Each of the vdd contact pad layers 76 is located above the source (for example, the first p⁺-type impurity layer 14a) of each of the load transistors Q5 and Q6. Each of the Vdd contact pad layers 76 is electrically connected to the source (for example, the first p⁺-type impurity layer 14a) of each of the load transistors Q5 and Q6 through the field/second-layer contact section 80.

8) Cross-Sectional Structure of Second Conductive Layer

Next, a cross-sectional structure of the second conductive layer is described with reference to FIG. 12 and FIG. 13. The second conductive layer may be formed only from, for example, a nitride layer of a refractory metal. The thickness of the second conductive layer may be for example 100 nm to 200 nm, and more specifically be 140 nm to 160 nm. The nitride layer of a refractory metal may be formed from, for example, titanium nitride. Because the second conductive layer is formed from a nitride layer of a refractory metal, the thickness of the second conductive layer may be made smaller, and miniaturizing processing thereof may be readily conducted. Accordingly, the cell area may be reduced.

Also, the second conductive layer may be composed in either one of the following embodiments. 1) It may have a structure in which a nitride layer of a refractory metal is formed on a metal layer formed from a refractory metal. In this case, the metal layer formed from a refractory metal is an under-layer, and may be composed of a titanium layer, for example. Titanium nitride may be listed as a material of the nitride layer of a refractory metal. 2) The second conductive layer may be composed only of a metal layer of a refractory metal.

Next, a cross-sectional structure of the field/second-layer contact section 80 is described with reference to FIG. 12 and FIG. 13. The field/second-layer contact section 80 is formed in a manner to fill a through hole 90a that is formed in the first interlayer dielectric layer 90. The field/second-layer contact section 80 includes a barrier layer 80a, and a plug 80b formed over the barrier layer 80a. Titanium and tungsten may be listed as material of the plugs. The barrier layer 80a may be formed from a metal layer of a refractory metal, and a nitride layer of a refractory metal formed over the metal layer. For example, titanium may be listed as material of the metal layer of a refractory metal. Titanium nitride, for example, may be listed as material of the nitride layer of a refractory metal.

Next, a cross-sectional structure of the first-layer/second-layer contact section 82 is described with reference to FIG. 12 and FIG. 13. The first-layer/second-layer contact section 82 is formed in a manner to fill a through hole 90b that is formed in the first interlayer dielectric layer 90. The first-layer/second-layer contact section 82 may have the same structure as that of the field/second-layer contact section 80 described above.

The diameter of each of the through holes 90a and 90b in the first interlayer dielectric layer 90 may be equal to or less than the diameter of a through hole 92a in a second interlayer dielectric layer 92 and a through hole 94a in a third interlayer dielectric layer 94 to be described below, and may be smaller than the diameter of each of the through holes 92a and 94a. The resultant effects will be described below in a section “Effects”. Each of the through holes 90a and 90b may have a minimum size that may be achieved by a manufacturing process technology applied to manufacturing the semiconductor device. The through holes 90a and 90b in the first interlayer dielectric layer 90 may be formed by a process described below.

A second interlayer dielectric layer 92 is formed in a manner to cover the second conductive layer. The second interlayer dielectric layer 92 may be formed through a planarization process using, for example, a chemical mechanical polishing method.

2.4 Third Conductive Layer

The third conductive layer is described below with reference to FIG. 5 and FIG. 10. It is noted that the third conductive layer means a conductive layer that is formed on the second interlayer dielectric layer 92 (see FIG. 12 and FIG. 13).

The third conductive layer includes an upper layer 32b of the second drain-gate wiring layer, a main word line 50, a vdd wiring 52, a second BL contact pad layer 70b, a second bar-BL contact pad layer 72b and a second Vss contact pad layer 74b.

The upper layer 32b of the second drain-gate wiring layer, the main word line 50 and the Vdd wiring 53 are formed in a manner to extend along the X direction. The second BL contact pad layer 70b, the second bar-BL contact pad layer 72b and the second Vss contact pad layer 74b are formed in a manner to extend in the Y direction.

Components of the third conductive layer are concretely described below

1) Upper Layer of the Second Drain-Gate Wiring Layer

The upper layer 32b of the second drain-gate wiring layer is formed in a manner to traverse the second drain-drain wiring layer 42 in the second conductive layer, as shown in FIG. 10. More concretely, the upper layer 32b of the second drain-gate wiring layer is formed from an area above the end portion 40b of the first drain-drain wiring layer 40 to an area above an end portion 32a 1 of the lower layer 32a of the second drain-gate wiring layer. The upper layer 32b of the second drain-gate wiring layer is electrically connected to the end portion 40b of the first drain-drain wiring layer 40 through a contact section between the second conductive layer and the third conductive layer (herein after referred to as a “second-layer/third-layer contact section”) 84. Also, the upper layer 32b of the second drain-gate wiring layer is electrically connected to the end portion 32a 1 of the lower layer 32a of the second drain-gate wiring layer through the second-layer/third-layer contact section 84.

As shown in FIG. 1, the first drain-drain wiring layer 40 in the second conductive layer and the second gate-gate electrode layer 22 in the first conductive layer are electrically connected to each other through the second-layer/third-layer contact section 84, the upper layer 32b of the second drain-gate wiring layer, the second-layer/third-layer contact section 84, the lower layer 32a of the second drain-gate wiring layer, and the first-layer/second-layer contact section 82.

2) Vdd Wiring

The Vdd wiring 52 is formed in a manner to pass over the Vdd contact pad layer 76, as shown in FIG. 10. The Vdd wiring 52 is electrically connected to the Vdd contact pad layer 76 through the second-layer/third-layer contact section 84.

3) Second BL Contact Pad Layer

The second BL contact pad layer 70b is located above the first BL contact pad layer 70a. The second BL contact pad layer 70b is electrically connected to the first BL contact pad layer 70a through the second-layer/third-layer contact section 84.

4) Second Bar-BL Contact Pad Layer

The second bar-BL contact pad layer 72b is located above the first bar-BL contact pad layer 72a. The second bar-BL contact pad layer 72b is electrically connected to the first bar-BL contact pad layer 72a through the second-layer/thirdlayer contact section 84.

5) Second Vss Contact Pad Layer

The second Vss contact pad layer 74b is located above the second Vss contact pad layer 74a. The second Vss contact pad layer 74b is electrically connected to the first Vss contact pad layer 74a through the second-layer/third-layer contact section 84.

6) Cross-sectional structure of Third Conductive Layer

Next, a cross-sectional structure of the third conductive layer is described with reference to FIG. 12 and FIG. 13. The third conductive layer has a structure in which, for example, a nitride layer of a refractory metal, a metal layer, and a nitride layer of a refractory metal, in this order from the bottom, are successively stacked in layers. For example, titanium nitride may be listed as material of the nitride layer of a refractory metal. Aluminum, copper or an alloy of these metals, for example, may be listed as material of the metal layer.

Next, a cross-sectional structure of the second-layer/third-layer contact section 84 is described. The second-layer/third-layer contact section 84 is formed in a manner to fill a through hole 92a formed in the second interlayer dielectric layer 92. The second-layer/third-layer contact section 84 may be provided with the same structure as that of the field/second-layer contact section 80 described above.

A third interlayer dielectric layer 94 is formed in a manner to cover the third conductive layer. The third interlayer dielectric layer 94 may be formed through a planarization process using, for example a chemical mechanical polishing method.

2.5 Fourth Conductive Layer

The fourth conductive layer is described below with reference to FIG. 6 and FIG. 11. It is noted that the fourth conductive layer means a conductive layer that is formed on the third interlayer dielectric layer 94.

The fourth conductive layer includes a bit line 60, a bit-bar line 62 and a Vss wiring 64.

The bit line 60, the bit-bar line 62 and the Vss wiring 64 are formed in a manner to extend along the Y direction.

Compositions of the bit line 60, the bit-bar line 62 and the Vss wiring 64 are concretely described below.

1) Bit Line

The bit line 60 is formed in a manner to pass over the second BL contact pad layer 70b, as shown in FIG. 11. The bit line 60 is electrically connected to the second BL contact pad layer 70b through a contact section between the third conductive layer and the fourth conductive layer (herein below referred to as a “third-layer/fourth-layer contact section”) 86.

2) Bit-Bar Line

The bit-bar line 62 is formed in a manner to pass over the second bar-BL contact pad layer 72b, as shown in FIG. 11. The bit-bar line 62 is electrically connected to the second bar-BL contact pad layer 72b through the third-layer/fourthlayer contact section 86.

3) Vss Wiring

The Vss wiring 64 is formed in a manner to pass over the second Vss contact pad layer 74b, as shown in FIG. 11. The Vss wiring 64 is electrically connected to the second Vss contact pad layer 74b through the third-layer/fourth-layer contact section 86.

4) Cross-Sectional Structure of Fourth Conductive Layer

Next, a cross-sectional structure of the fourth conductive layer is described with reference to FIG. 12 and FIG. 13. The fourth conductive layer may have the same structure as the structure of the third conductive layer described above.

Next, a cross-sectional structure of the third-layer/fourth-layer contact section 86 is described. The third-layer/fourth-layer contact section 86 is formed in a manner to fill a through hole 94a that is formed in the third interlayer dielectric layer 94. The third-layer/fourth-layer contact section 86 may have the same structure as the structure of the field/second-layer contact section 80 described above.

The diameter of the through hole 94a in the third interlayer dielectric layer 94 may be smaller than that of the through hole 92a in the second interlayer dielectric layer 92. In other words, the higher the interlayer dielectric layer in layers, the greater the diameter of the through hole may be set.

Although not shown in FIG. 12 or FIG. 13, a passivation layer may be formed on the fourth conductive layer.

3. Effects

Effects provided by the semiconductor device in accordance with the present embodiment are described below.

(1) A first drain-gate wiring layer and a second draingate wiring layer could be formed in the same conductive layer. However, in this case, it is difficult to reduce the cell area due to the high pattern density of the conductive layer where the first and second drain-gate wiring layers are formed.

However, in accordance with the present embodiment, the first drain-gate wiring layer 30 is located in the first conductive layer. Also, the second drain-gate wiring layer has a structure that is divided into the lower layer 32a of the second drain-gate wiring layer and the upper layer 32b of the second drain-gate wiring layer. The lower layer 32a of the second drain-gate wiring layer is located in the second conductive layer, and the upper layer 32b of the second drain-gate wiring layer is located in the third conductive layer. Consequently, the first drain-gate wiring layer and the second drain-gate wiring layer are formed in different layers, respectively. Accordingly, since the first draingate wiring layer and the second drain-gate wiring layer are not formed in the same layer, the pattern density of the wiring layer may be reduced. As a result, with the memory cell in accordance with the present embodiment, the cell area may be reduced.

(2) In accordance with the present embodiment, the diameter of each of the through holes 90a and 90b in the first interlayer dielectric layer 90 is less than the diameter of each of the through hole 92a in the second interlayer dielectric layer 92 and the through hole 94a in the third interlayer dielectric layer 94. As a result, due to the reasons described below, short-circuit of the contact sections 80 and 82 with a conductive section that is not supposed to connect to the contact sections 80 and 82 (for example, short-circuit between the field/second-layer contact section 80 and the first conductive layer) may be restricted.

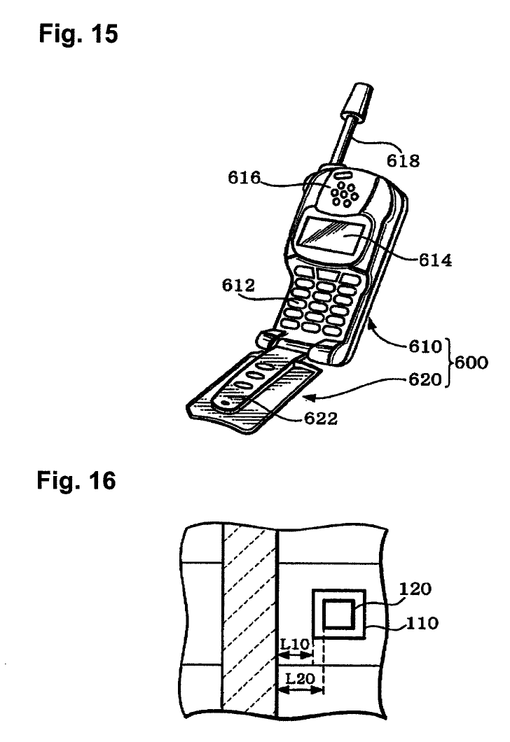

For example, let us consider a through hole for connecting the field and the second conductive layer. When the distance between the center of the through hole and the first conductive layer is constant, the greater the diameter of the through hole, the shorter the distance between the through hole and the first conductive layer becomes. More concretely, as shown in FIG. 16, the distance L10 between the through hole 110 having a greater diameter and the first conductive layer is smaller than the distance L20 between the through hole 120 having a smaller diameter and the first conductive layer. As the distance between the through hole and the first conductive layer becomes shorter, the contact section to be provided in the through hole would more likely be short-circuited with the first conductive layer. Accordingly, the greater the diameter of the through hole in the first interlayer dielectric layer, the more the field/second-layer contact section 80 would likely be short-circuited with the first conductive layer.

However, in accordance with the present embodiment, the diameter of each of the through holes 90a and 90b in the first interlayer dielectric layer is less than the diameter of the through hole 92a in the second interlayer dielectric layer and the diameter of the through hole 94a in the third interlayer dielectric layer. Consequently, in accordance with the present embodiment, the gap between the through hole 90a and the first conductive layer has more room compared to the case in which, for example, the diameter of each of the through holes 90a and 90b in the first interlayer dielectric layer is set to be greater than the diameter of each of the through holes 92a and 94a in the second and third interlayer dielectric layers. As a result, short-circuit of the contact sections 80 and 82 with a conductive section that is not supposed to connect to the contact sections 80 and 82 (for example, short-circuit between the field/second-layer contact section 80 and the first conductive layer) may be restrained. Accordingly, the yield is improved.

Also, in accordance with the present embodiment, the through holes 90a and 90b provided with a smaller diameter to restrain short-circuit. For this reason, short-circuit may be restrained without causing an increase in the width of the memory cell.

(3) Because the diameter of each of the through holes 90a and 90b in the first interlayer dielectric layer is smaller than the diameter of each of the through holes 92a and 94a in the second interlayer dielectric layer and the third interlayer dielectric layer 92 and 94, the gap between the through hole 90a and the first interlayer dielectric layer 90 has greater room. For this reason, as a result, short-circuit of the contact sections 80 and 82 with a conductive section that is not supposed to connect to the contact sections 80 and 82 (for example, short-circuit between the field/second-layer contact section 80 and the first conductive layer) may be restrained better.

Also, in this case, the diameter of the through holes 92a and 94a in the second and third interlayer dielectric layers 92 and 94 is greater than the diameter of the through hole 90a in the first interlayer dielectric layer 90. In general, the greater the diameter, the easier the through hole may be formed. As a result, in this case, short-circuit of the contact sections 80 and 82 in the first interlayer dielectric layer 90 with a certain conductive section may be restrained, while the through holes 92a and 94a in the second and third interlayer dielectric layers 92 and 94 can be readily formed.

(4) When many through holes are present, it is generally difficult to provide sufficient room in the gaps between the through holes and certain conductive sections. Accordingly, the embodiment described above is suitable to a device having many through holes in the first interlayer dielectric layer.

4. Method of Forming Contact Sections

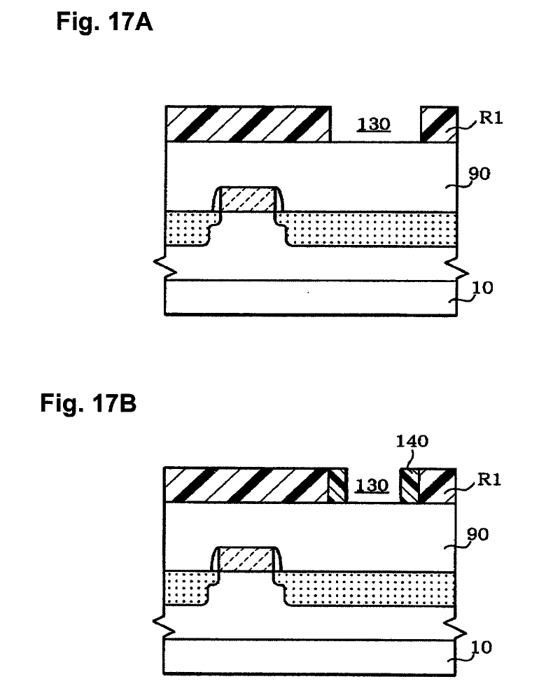

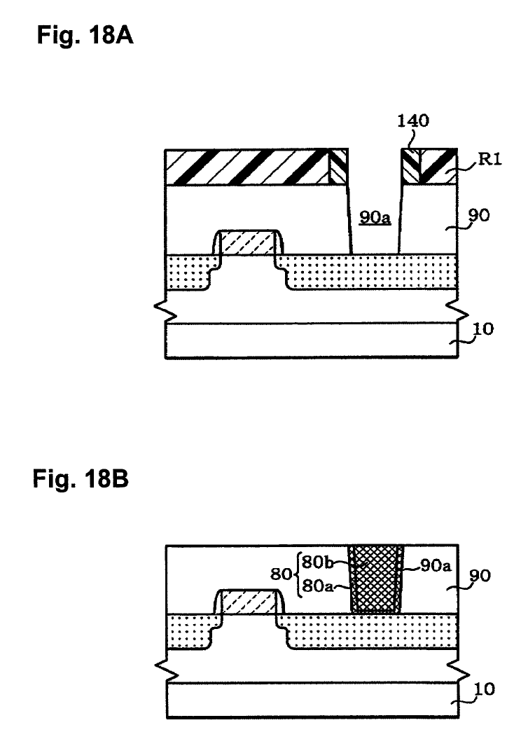

A method of forming a contact section in the first interlayer dielectric layer is described as an example. FIGS. 17A, 17B, 18A and 18B schematically show in cross sections the steps of forming a contact section in the first interlayer dielectric layer.

As shown in FIG. 17A, a resist layer R1 having a given pattern is formed on the interlayer dielectric layer 90 that is formed on the semiconductor layer 10. An opening 130 in 25 the resist layer R1 is set have a diameter that is greater than a diameter of a through hole to be obtained.

Next, relax agent (not shown) is formed on a surface of the resist layer R1.

Next, the relax agent and the resist layer R1 are reacted to form a relax layer 140 on a sidewall of the resist layer R1 in the opening 130. By the relax layer 140 formed thereon, the diameter of the opening 130 is narrowed by a corresponding amount to adjust to the diameter of the through hole to be obtained. The relax agent and the resist layer R1 may be reacted, for example, in the following manner.

Next, the interlayer dielectric layer 90 is etched using the resist layer R1 and the relax layer 140 as a mask, to thereby form a through hole 90a, as shown in FIG. 18A. Next, as shown in FIG. 18B, a barrier layer 80a and a plug 80b are formed in the through hole 90a, to form a contact section 80.

By forming the contact section 80 in the manner described above, the contact section having a smaller diameter can be readily formed.

5. Example of Application of SRAM to Electronic Apparatus

The SRAM in accordance with the present embodiment may be applied to electronic apparatus, such as, for example, mobile equipment. FIG. 14 shows a block diagram of a part of a mobile telephone system. A CPU 540, an SRAM 550 and a DRAM 560 are mutually connected via a bus line. Further, the CPU 540 is connected to a keyboard 510 and an LCD driver 520 via the bus line. The LCD driver 520 is connected to a liquid crystal display section 530 via the bus line. The CPU 540, the SRAM 550 and the DRAM 560 compose a memory system.

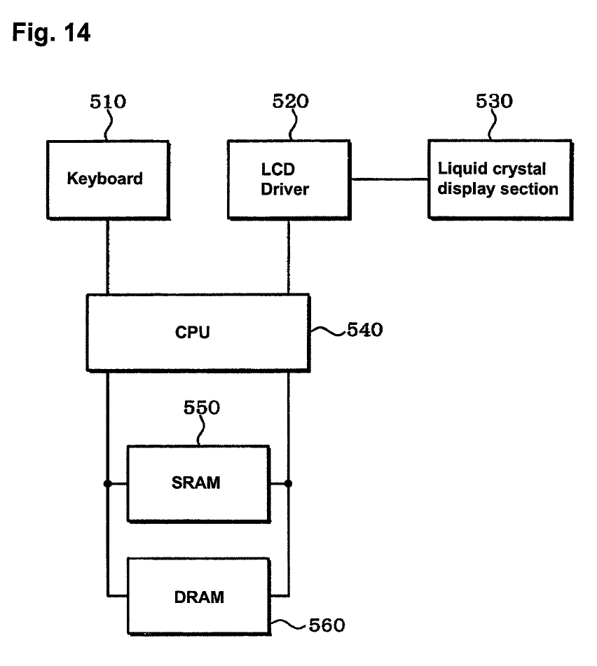

FIG. 15 shows a perspective view of a mobile telephone 600 that is provided with the mobile telephone system shown in FIG. 14. The mobile telephone 600 is provided with a main body section 610 including a keyboard 612, a liquid crystal display section 614, a receiver section 616 and an antenna section 618, and a lid section 620 including a transmitter section 622.

The present invention is not limited to the embodiment described above, and a variety of modifications may be made within the scope of the subject matter of the present invention.

For example, it is not limited to a six-transistor type SRAM, but it may be also applied to an SRAM of four-transistor and two-resistor type.

What is claimed is:

1. A semiconductor device provided with a memory cell including a first driver transistor, a second driver transistor, a first transfer transistor, and a second transfer transistor, a first load transistor, and a second load transistor, the semiconductor device comprising:
a field in which a source region and a drain region of each of the first and the second driver transistors, the first and the second transfer transistors and the first and the second load transistors;
a first conductive layer formed on the field;
a second conductive layer located in a layer over the first conductive layer; and
a first interlayer dielectric layer formed between the first conductive layer and the second conductive layer; and
a second interlayer dielectric layer located in a layer over the first interlayer dielectric layer,
wherein a first through hole is formed in the first interlayer dielectric layer, and a second through hole is formed in the second interlayer dielectric layer, and
wherein a diameter of the first through hole is equal to or less than a diameter of the second through hole.

2. The semiconductor device according to claim 1,
wherein the memory cell comprises:
a first gate-gate electrode layer including a gate electrode of the first load transistor and a gate electrode of the first driver transistor;
a second gate-gate electrode layer including a gate electrode of the second load transistor and a gate electrode of the second driver transistor;
a first drain-drain wiring layer which forms a part of an electrical connection between a drain region of the first load transistor and a drain region of the first driver transistor;
a second drain-drain wiring layer which forms a part of an electrical connection between a drain region of the second load transistor and a drain region of the second driver transistor;
a first drain-gate wiring layer which forms a part of an electrical connection between the first gate-gate electrode layer and the second drain-drain wiring layer; and
a second drain-gate wiring layer which forms a part of an electrical connection between the second gate-gate electrode layer and the first drain-drain wiring layer, and
wherein the first drain-gate wiring layer and the second drain-gate wiring layer are located in different conductive layers, respectively.

3. The semiconductor device according to claim 1, wherein a diameter of the first through hole is smaller than a diameter of the second through hole.

4. The semiconductor device according to claim 1, wherein the first through hole has a minimum size that is achieved by a manufacturing process technology applied to manufacturing the semiconductor device.

5. The semiconductor device according to claim 1, wherein the first through hole is formed by using a first mask layer and a second mask layer which is provided on a sidewall of an opening of the first mask layer.

6. The semiconductor device according to claim 5, wherein the first through hole is formed by a process including a step of forming the first mask layer, and a step of forming the second mask layer on a sidewall of the opening of the first mask layer.

7. The semiconductor device according to claim 5, wherein the first mask layer is a resist layer, and the second mask layer adjust s a width of the opening of the mask layer.

8. The semiconductor device according to claim 1,
wherein the first drain-gate wiring layer is electrically connected to the second drain-drain wiring layer through a contact section, and
wherein the second drain-gate wiring layer is electrically connected to the second gate-gate electrode layer through a contact section, and electrically connected to the first drain-drain wiring layer through a contact section.

9. The semiconductor device according to claim 1, wherein the first drain-gate wiring layer is located in a layer below the second drain-gate wiring layer.

10. The semiconductor device according to claim 1, wherein the first drain-gate wiring layer is located in a layer in which the first gate-gate electrode layer is provided.

11. The semiconductor device according to claim 1, wherein the second drain-gate wiring layer is formed across a plurality of layers.

12. The semiconductor device according to claim 11,
wherein the second drain-gate wiring layer includes a lower layer of the second drain-gate wiring layer and an upper layer of the second drain-gate wiring layer, and
wherein the upper layer is located in a layer over the lower layer, and is electrically connected to the lower layer.

13. The semiconductor device according to claim 12, wherein the upper layer is electrically connected to the lower layer through a contact section.

14. The semiconductor device according to claim 12,
wherein the first gate-gate electrode layer, the second gate-gate electrode layer and the first drain-gate wiring layer are located in a first conductive layer,
wherein the first drain-drain wiring layer, the second drain-drain wiring layer and the lower layer are located in a second conductive layer, and
wherein the upper layer is located in a third conductive layer.

15. The semiconductor device according to claim 1, wherein the second conductive layer is a nitride layer of a refractory metal.

16. The semiconductor device according to claim 1, wherein the second conductive layer has a thickness of 100 nm to 200 nm.

17. A memory system provided with the semiconductor device defined in any one of claims 1 to 16.

18. An electronic apparatus provided with the semiconductor device defined in any one of claims 1 to 16.
